(19) United States
(12) Patent Application Publication
(10) Pub. No.: US 2013/0181232 A1
(43) Pub. Date: Jul. 18, 2013

(54) Optocoupler with Surface Functional Coating Layer

(71) Applicants: Premkumar Jeromerajan, Singapore (SG); Gopinath Maasi, Singapore (SG); Gary Tay Thiam Siew, Singapore (SG)

(72) Inventors: Premkumar Jeromerajan, Singapore (SG); Gopinath Maasi, Singapore (SG); Gary Tay Thiam Siew, Singapore (SG)

(73) Assignee: Avago Technologies ECBU IP (Singapore) Pte. Ltd., Fort Collins, CO (US)

(21) Appl. No.: 13/352,245

(22) Filed: Jan. 17, 2012

(51) Int. Cl. H01L 31/167; H01L 31/18

(52) U.S. Cl. 257/81; 438/25; 257/E31.108

(57) ABSTRACT

Various embodiments of methods and devices are provided for an optocoupler comprising an optically reflective compound comprising silicone and inner and outer surfaces. A molding compound surrounds and encapsulates at least portions of the outer surfaces of the optically reflective compound to form an enclosure. A surface functional coating layer is provided in the optically reflective compound to promote adhesion and increase breakdown voltages between inner walls of the enclosure and the outer surfaces of the optically reflective compound.

### FIELD OF THE INVENTION

Various embodiments of the invention described herein relate to the field of optocouplers and optical isolators.

### BACKGROUND

In electronics, an optocoupler, also known as an opto-isolator, photocoupler, or optical isolator, is an electronic device that transfers electrical signals using light waves to provide coupling with electrical isolation between the input and output of the optocoupler. The main purpose of an optocoupler is to prevent high voltages or rapidly changing voltages on one side of the optocoupler from damaging components or distorting transmissions on the other side of the optocoupler. By way of example, some commercially available optocouplers are designed to withstand input-to-output voltages of up to 10 kV and voltage transients with speeds up to 10 kV/μsec.

In an optocoupler, input and output sides of the device are connected with a beam of light (typically falling in the infrared or near-infrared spectrum) modulated by input currents proportional to the electrical signals input to the device. The optocoupler transforms the input electrical signals into light, sends the corresponding light signals across a dielectric channel, captures the transmitted light signals on the output side of the optocoupler, and transforms the transmitted light signals back into output electric signals. Some optocouplers employ infrared or near-infrared light emitting diodes (LEDs) to transmit the light signals and photodetectors to detect the light signals and convert them into output electrical signals.

Many commercially available optocouplers are provided in standard 8-pin dual in-line (DIP) or other standard format packages. In such packages, the LED and photodetector thereof are disposed inside the package, and encapsulated in an optically clear or transmissive silicone material. Light emitted by the LED is reflected from a layer of reflective material, typically a white silicone, which encapsulates the clear silicone material. Light reflected from the reflective material is detected by the photodetector. The reflective encapsulating material sometimes separates and delaminates from an epoxy molding compound, which surrounds the reflective encapsulating material, and to which the reflective encapsulating material is intended to be adhered. Such separation and delamination can be exacerbated by high voltages. Among other things, what is needed is an optocoupler package having improved adhesion between the reflective encapsulating material and the surrounding molding compound.

### SUMMARY

In one embodiment, there is provided an optocoupler package comprising a light emitting diode (LED), at least one photodetector, a first lead frame comprising an LED connection site and a first pin connection portion, a second lead frame comprising a photodetector connection site and a second pin connection portion, a molding compound comprising epoxy, an optically reflective compound comprising silicone and inner and outer surfaces, wherein the LED IC is operably connected to the first lead frame at the LED connection site, the photodetector is operably connected to the second lead frame at the photodetector connection site, the molding compound surrounds and encapsulates portions of the first and second lead frames between the die connection sites and pin connection portions thereof to form an enclosure, the enclosure comprising an interior chamber having inner walls engaging and in contact with at least portions of the outer surfaces of the optically reflective compound, the LED and photodetector are disposed within the chamber and configured with respect to at least portions of the inner surfaces of the optically reflective compound such that at least portions of light emitted by the LED are reflected from the at least portions of such inner surfaces towards the photodetector, and the outer surfaces of the optically reflective compound comprise a surface functional coating layer configured to promote adhesion and increase breakdown voltages between the inner walls of the enclosure and the outer surfaces of the optically reflective compound.

In another embodiment, there is provided a method of making an optocoupler package comprising a light emitting diode (LED), at least one photodetector, a first lead frame comprising an LED connection site and a first pin connection portion, a second lead frame comprising a photodetector connection site and a second pin connection portion, a molding compound comprising epoxy, and an optically reflective compound comprising silicone inner and outer surfaces, the method comprising attaching the LED to the LED connection site on the first lead frame and then wirebonding same to the first lead frame to form first wirebonds, attaching the photodetector to the photodetector connection site on the second lead frame and then wirebonding same to the second lead frame to form second wire bonds, encapsulating the LED, the photodetector, and portions of the first and second lead frames disposed near the LED and the photodetector with an optically transmissive compound comprising silicone, encapsulating the optically transmissive compound and portions of the first and second lead frames with an optically reflective compound comprising silicone, the optically reflective compound comprising inner surfaces that engage the optically transmissive compound and outer surfaces, treating at least portions of the outer surfaces of the optically reflective compound to form a surface functional coating layer thereon, and overmolding the outer surfaces of the optically reflective compound and portions of the first and second lead frames with a molding compound comprising epoxy to form an enclosure having inner walls, wherein the surface functional coating layer is configured to promote adhesion and increase breakdown voltages between the inner walls of the enclosure and at least portions of the outer surfaces of the optically reflective compound.

Further embodiments are disclosed herein or will become apparent to those skilled in the art after having read and understood the specification and drawings hereof.

### BRIEF DESCRIPTION OF THE DRAWINGS

Different aspects of the various embodiments will become apparent from the following specification, drawings and claims in which:

FIG. 1 illustrates one embodiment of a schematic circuit diagram for an optocoupler 8-pin DIP package 10;

FIGS. 2 through 5 shown various embodiments of circuitry 11 that may be employed in optocoupler package 10;

FIGS. 6, 7 and 8 show top, end and side views of an 8-pin DIP package configuration corresponding to the embodiment of the circuitry shown in FIG. 1;

FIG. 9 shows a cross-sectional view according to one embodiment of optocoupler package 10;

FIGS. 10(a) through 10(d) illustrate one embodiment of making package 10;

FIG. 11 shows one embodiment of method 100 of making package 10;

FIGS. 12(a) and 12(b) show one embodiment of treating compound 30 to form the SFCL (Surface Functional Coating Layer) along and into outer surfaces 34;

FIGS. 13(a) and 13(b) illustrate covalent bonding by means of epoxy polymer-amine groups (NH₂ or NH) between optically reflective compound 30 and molding compound 28;

FIG. 14 shows experimental results obtained using one embodiment of optically reflective compound 30 before and after plasma treatment to form the SFCL in outer surfaces 34 thereof, and

FIGS. 15 and 16 illustrate some embodiments of equipment that can be used to treat optically reflective compound 30 to form the SFCL along and into surfaces 34 thereof.

The drawings are not necessarily to scale. Like numbers refer to like parts or steps throughout the drawings.

### DETAILED DESCRIPTIONS OF SOME EMBODIMENTS

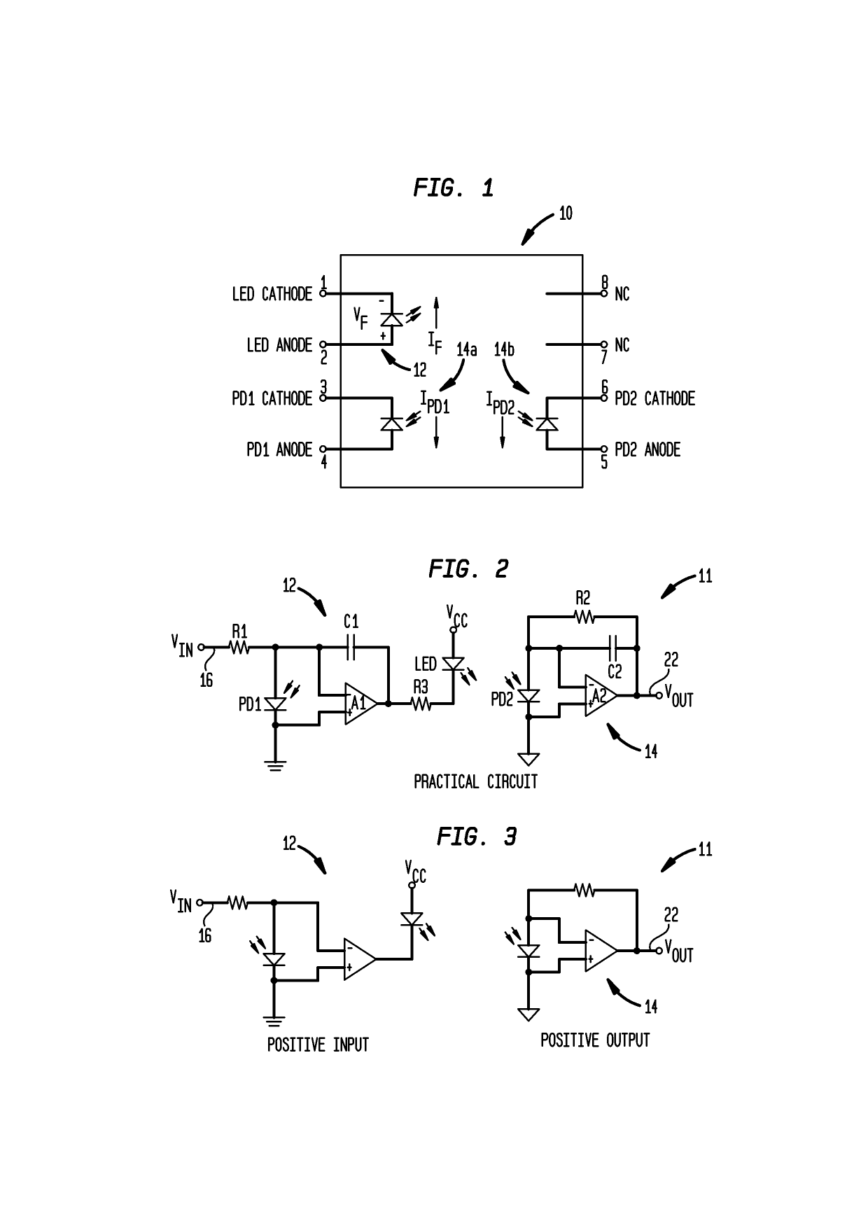

FIG. 1 illustrates one embodiment of a schematic circuit diagram for an optocoupler 8-pin DIP package 10 that may be employed in accordance with the teachings set forth herein. In FIG. 1, optocoupler package 10 comprises first and second input signal terminals corresponding to pins 1 and 2, respectively, and first and second output terminals corresponding to pins 3 and 4, respectively, and third and fourth output terminals corresponding to pins 5 and 6. Light emitting diode (LED) 30 is operably connected to the first and second input signal terminals and is configured to emit infrared or near-infrared light in proportion to at least one predetermined characteristic of input signals received across the first and second input signal terminals. First photodetector 14a is operably connected to the first and second output terminals and is configured to provide LED feedback control signals thereacross. Second photodetector 14b is operably connected to the third and fourth output terminals and is configured to provide isolated output signals thereacross.

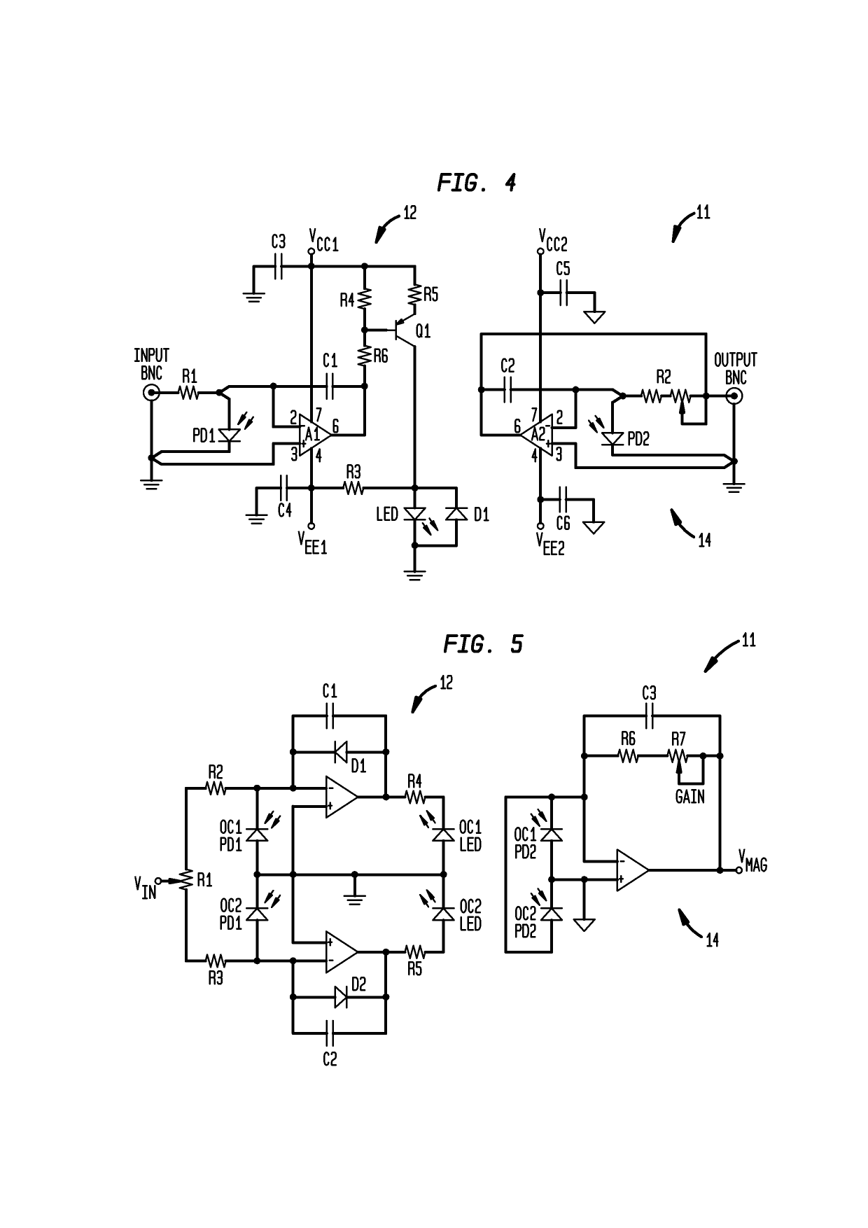

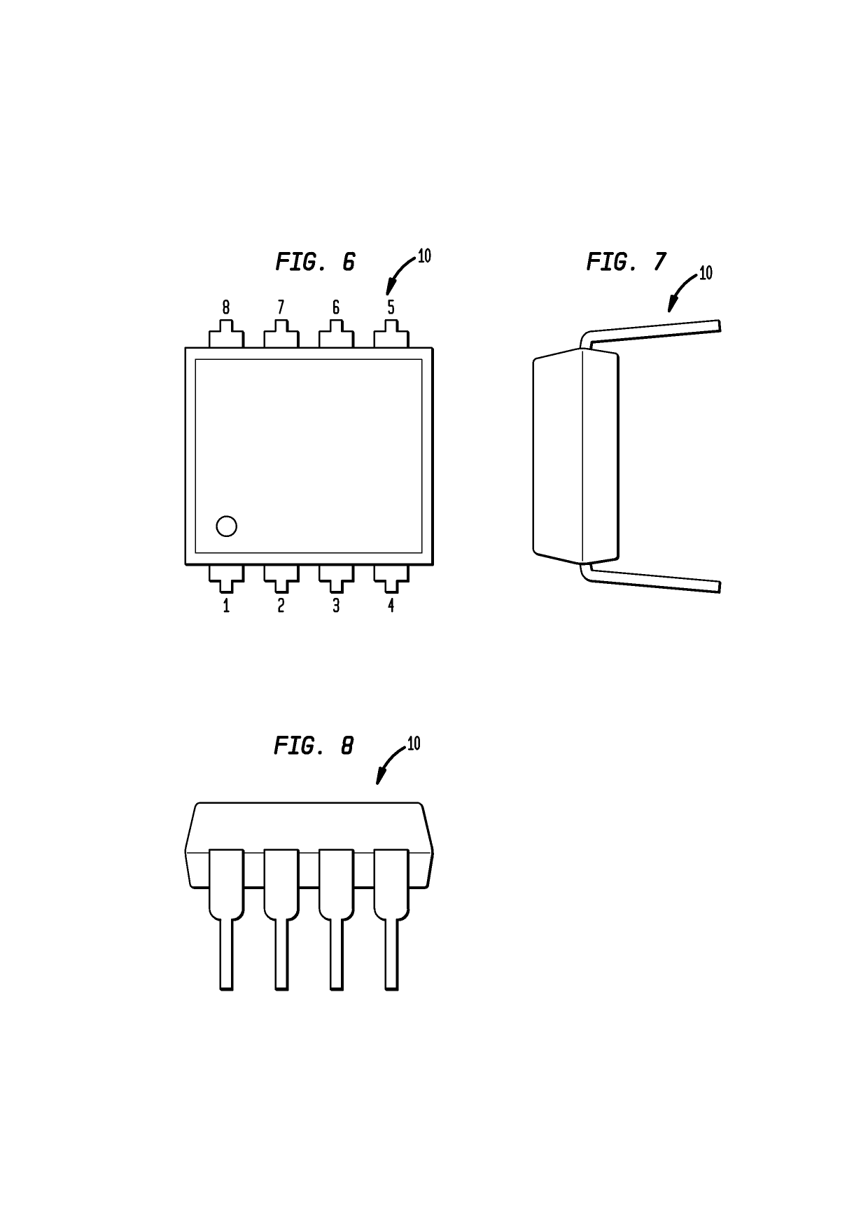

Referring now to FIGS. 2 through 5, there are shown various embodiments of circuitry 11 that may be employed in optocoupler package 10 to provide isolated output signals across the output terminals thereof. For example, FIG. 2 shows a “practical circuit” 11 configured to be non-inverting with positive input and negative output voltages and that includes components configured to stabilize the input portions of the circuit. FIG. 3 shows a unipolar embodiment for circuit 11 that accommodates both positive and negative input and output voltages. FIG. 4 shows a precision analog isolation amplifier embodiment of circuit 11. FIG. 5 shows a bipolar isolation amplifier embodiment of circuit 11. FIGS. 6, 7 and 8 show top, end and side views of an 8-pin DIP package configuration corresponding to the embodiment of the circuitry shown in FIG. 1.

Further details regarding the foregoing circuits and packaging formats may be found in the publication “HCNR200 and HCNR201 High-Linearity Analog Optocouplers,” Avago Technologies™, Dec. 10, 2011, the Data Sheet for which is filed on even date herewith in an accompanying Information Disclosure Statement, and the entirety of which is hereby incorporated by reference herein.

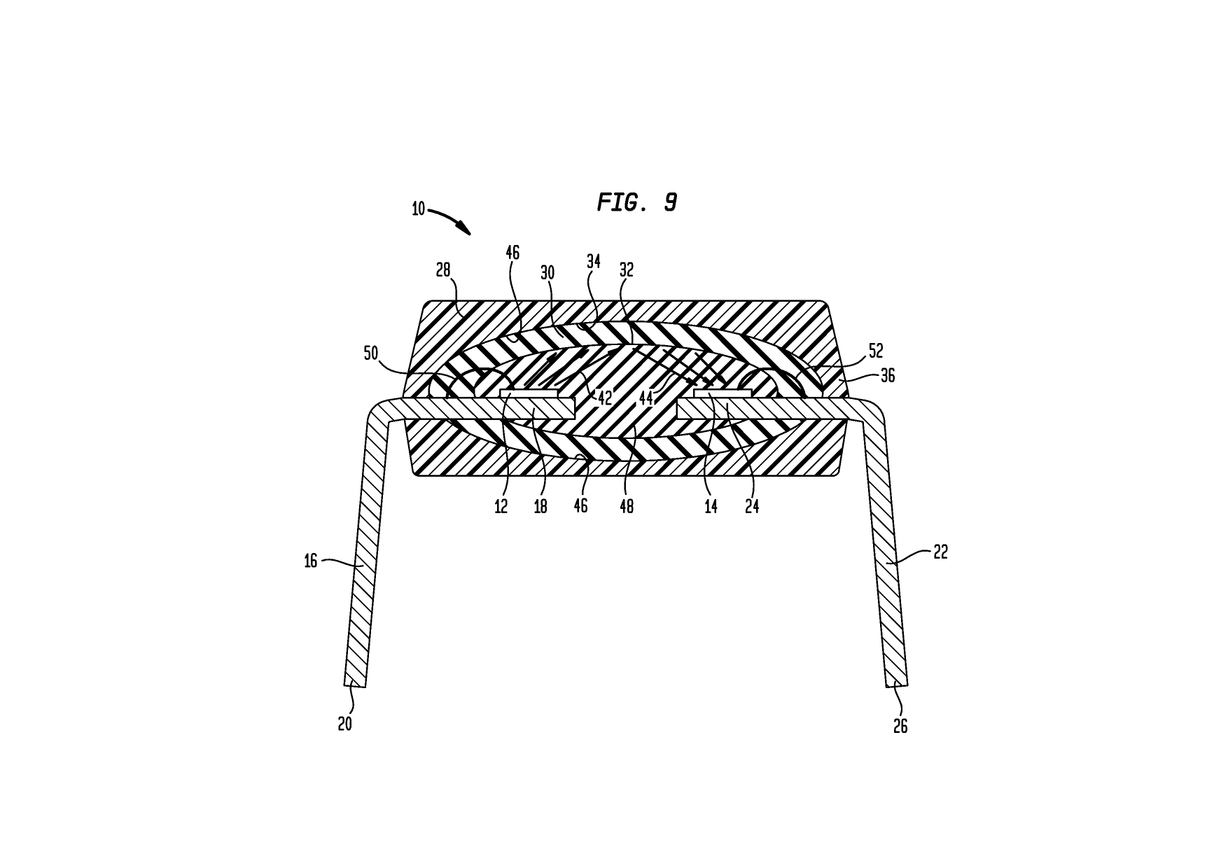

FIG. 9 shows a cross-sectional view according to one embodiment of optocoupler package 10 comprising light emitting diode (LED) 12, photodetector 14, first lead frame 16 comprising LED connection site 18 and first pin connection portion 20. In FIG. 9, optocoupler package 10 further comprises second lead frame 22 comprising photodetector connection site 24 and second pin connection portion 26. According to some embodiments, LED 12 is an AlGaAs LED, an ACE AlGaAs LED, a DPUP AlGaAs LED, a GaAsP LED or any other suitable type of LED. According to some embodiments, photodetector 14 is a photo diode, a bipolar detector transistor, a Darlington detector transistor, or any other suitable type of photodetector. In addition, and according to some embodiments, molding compound 28 comprises epoxy and plastic, and optically reflective compound 30 comprises silicone and inner and outer surfaces 32 and 34, respectively. Molding compound 28 may comprise, by way of example, plastic or any other suitable material.

Continuing to refer to FIG. 9, and according to one embodiment, LED 12 is an integrated circuit (IC) die that is operably connected to first lead frame 16 at LED connection site 18, and photodetector 14 is operably connected to second lead frame 22 at photodetector connection site 24. Molding compound 28 surrounds and encapsulates portions of first and second lead frames 16 and 22 that are disposed between die connection sites 18 and 24, on the one hand, and pin connection portions 20 and 26 on the other hand, to form an enclosure 36. One example of a molding compound 28 suitable for use in package 10 is epoxy molding compound MP-150SG manufactured by Nitto Denko Corporation of Japan. Enclosure 36 comprises an interior chamber having inner walls 46 that engage and are in contact with at least portions of outer surfaces 34 of optically reflective compound 30. LED 12 and photodetector 14 are disposed within the chamber and are configured with respect to at least portions of inner surfaces 32 of optically reflective compound 30 such that at least portions of light 42 emitted by LED 12 are reflected as light 44 from the at least portions of such inner surfaces 32 towards photodetector 14.

Outer surfaces 34 of optically reflective compound 30 have disposed and formed thereon a surface functional coating layer (“SFCL”) configured to promote adhesion and increase breakdown voltages between inner walls 46 of enclosure 36 and outer surfaces 34 of the optically reflective compound. Note that in one embodiment inner walls 46 extend all the way around and inside enclosure 36, and that the SFCL may be configured to be in contact with all such portions of inner walls 46 of enclosure 36, or with selected portions of such inner walls 46. Note further that the SFCL contained in outer surfaces 34 of optically reflective compound 30 may be covalently bonded to at least portions of inner walls 46. The SFCL may also comprise hydroxyl functional groups. According to one embodiment, the interface between the SFCL and inner walls 46 may be configured to withstand breakdown voltages of at least about 8 kV, at least about 10 kV, and at least about 12 kV. Other breakdown voltages are also contemplated. Good coupling and adhesion between optically reflective compound 30 and molding compound 28 is promoted by the SFCL contained in outer surfaces 34 of optically reflective compound 30.

Continuing to refer to FIG. 9, an optically transmissive compound 48 comprising silicone may be disposed between inner surfaces 32 of optically reflective compound 30 and LED 12 and photodetector 14. Examples of materials suitable for use as optically transmissive compound 48 are Dow Corning™ LED materials. According to one embodiment, optically reflective compound 30 may comprise white silicone or alternatively clear silicone mixed with white particles or powder of, for example, calcium carbonate or titanium dioxide, to form a white silicone. As shown in FIG. 9, LED 12 is wirebonded to first lead frame 16 via wirebond 50, and photodetector 14 is wirebonded to second lead frame 22 via wirebond 52. Molding compound 28 may comprise a black epoxy molding compound, as is well known in the art. In the embodiment of package 10 shown in FIG. 9, optocoupler package 10 is an 8-pin dual in-line package (DIP). Other packaging formats, configurations and designs are contemplated as well. Note that package 10 may also be an opto-isolator.

Various optocouplers and optocoupler packages known in the art may be adapted for use in accordance with the above teachings. Examples of such optocouplers and optocoupler packages include, but are not limited to: (a) Avago Technologies™ “6N135/6, HCNW135/6, HCPL-2502/0500/0501 Single Channel, High Speed Optocouplers,” Jan. 29, 2010; (b) Avago Technologies™ HCPL-7710/0710 40 ns Propagation Delay CMOS Optocoupler,” Jan. 4, 2008; and (c) Avago Technologies™ “6N137, HCNW2601, HCNW2611, HCPL-0600, HCPL-0601, HCPL-0611, HCPL-0630, HCPL-0631, HCPL-0661, HCPL-2601, HCPL-2611, HCPL-2630, HCPL-2631, HCPL-4661 High CMR, High Speed TTL Compatible Optocouplers,” Mar. 29, 2010; the respective Data Sheets for which are filed on even date herewith in an accompanying Information Disclosure Statement and which are hereby incorporated by reference herein, each in its respective entirety.

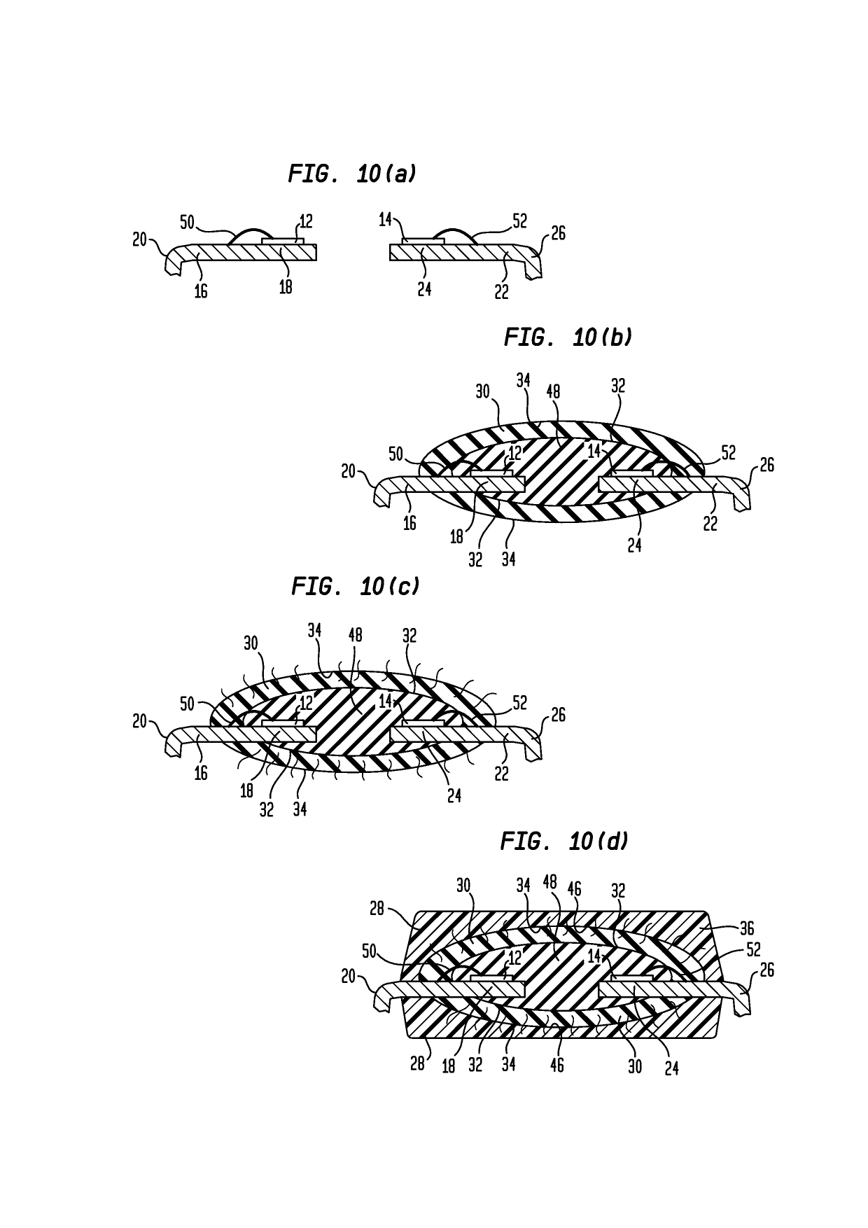

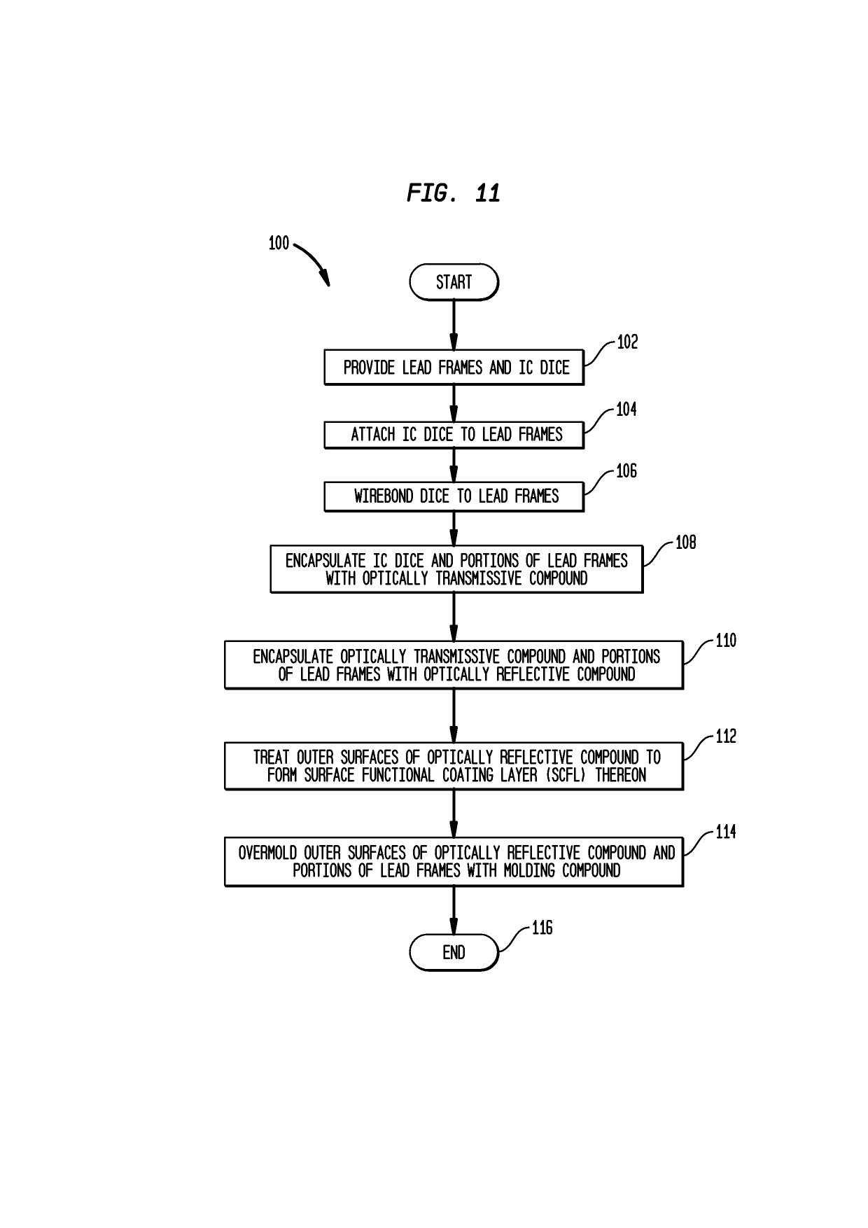

Referring now to FIGS. 10(a) through 10(d), and to method 100 of FIG. 11, there are shown several steps according to one embodiment of a method for making optocoupler 10. In FIG. 10(a) there are shown lead frames 16 and 22 with LED IC die 12 affixed to LED connection site 28 and photodetector IC die 14 affixed to photodetector connection site 24. Wire bonds 50 and 52 attach LED die to first lead frame 16 and photodetector 14 to second lead frame 22. See corresponding steps 102 through 106 of method 100 in FIG. 11, where LED 12 is attached to LED connection site 18 on first lead frame 16 and then wirebonded to first lead frame 16 to form first wirebond 50. Photodetector 14 is attached to photodetector connection site 24 on second lead frame 22 and then wirebonded to second lead frame 22 to form second wire bond 52.

Referring now to FIG. 10(b) and to step 108 of FIG. 11, LED 12, photodetector 14, and portions of first and second lead frames 16 and 22 disposed near LED 12 and photodetector 14 are encapsulated with optically transmissive compound 48, which according to one embodiment comprises silicone.

Referring now to FIGS. 10(a) and 10(b) and to step 110 of FIG. 11, optically transmissive compound 48, and portions of first and second lead frames 16 and 22, are encapsulated with optically reflective compound 30, which as described above and according to one embodiment comprises silicone. Optically reflective compound 30 comprises inner surfaces 32 that engage optically transmissive compound 48 and outer surfaces 34 that engage inner walls 46 of molding compound 28 and enclosure 36.

Referring now to FIG. 10(c) and to step 112 of FIG. 11, at least portions of outer surfaces 34 of optically reflective compound 30 are treated to form a surface functional coating layer (SFCL) thereon, as denoted by the squiggly lines of FIGS. 10(c) and (d), more about which is said below.

In FIG. 10(d) and in step 114 of method 100 shown in FIG. 11, outer surfaces 34 of optically reflective compound 30 and portions of first and second lead frames 16 and 22 are overmolded with a molding compound 28 comprising epoxy to form an enclosure 36 having inner walls 46. The surface functional coating layer (SFCL) formed along and into outer surfaces 34 of optically reflective compound 30 is configured to promote adhesion and increase breakdown voltages between inner walls 46 of enclosure 36 and at least portions of outer surfaces 34 of optically reflective compound 30.

According to one embodiment, the treating step where the SFCL is formed along and into outer surfaces 34 of optically reflective compound 30 comprises plasma treating at least portions of outer surfaces 34. Plasma treating may comprise employing a carrier gas such as argon, helium, nitrogen or any other suitable inert gas or mixture of carrier gases. Plasma treating may also comprise any one or more of providing employing a carrier gas at a rate ranging between about 1.0 liters per minute and about 10 liters per minute, employing a reaction gas comprising oxygen, employing a reaction gas at a rate ranging between about 10 standard cubic centimeters per minute (sccm) and about 50 sccm, plasma treating compound 30 at approximately atmospheric pressure, and employing radio frequency (RF) power ranging between about 50 watts and about 200 watts during the plasma treating process.

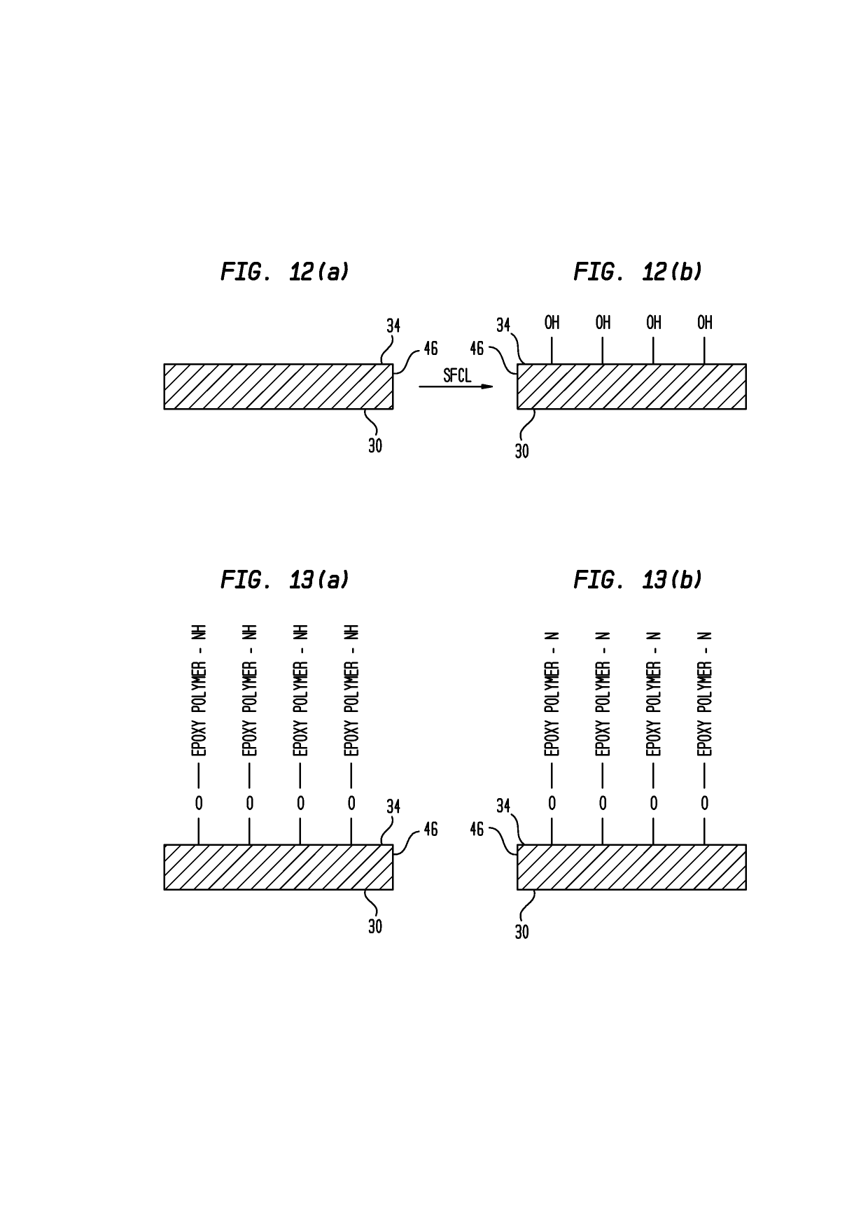

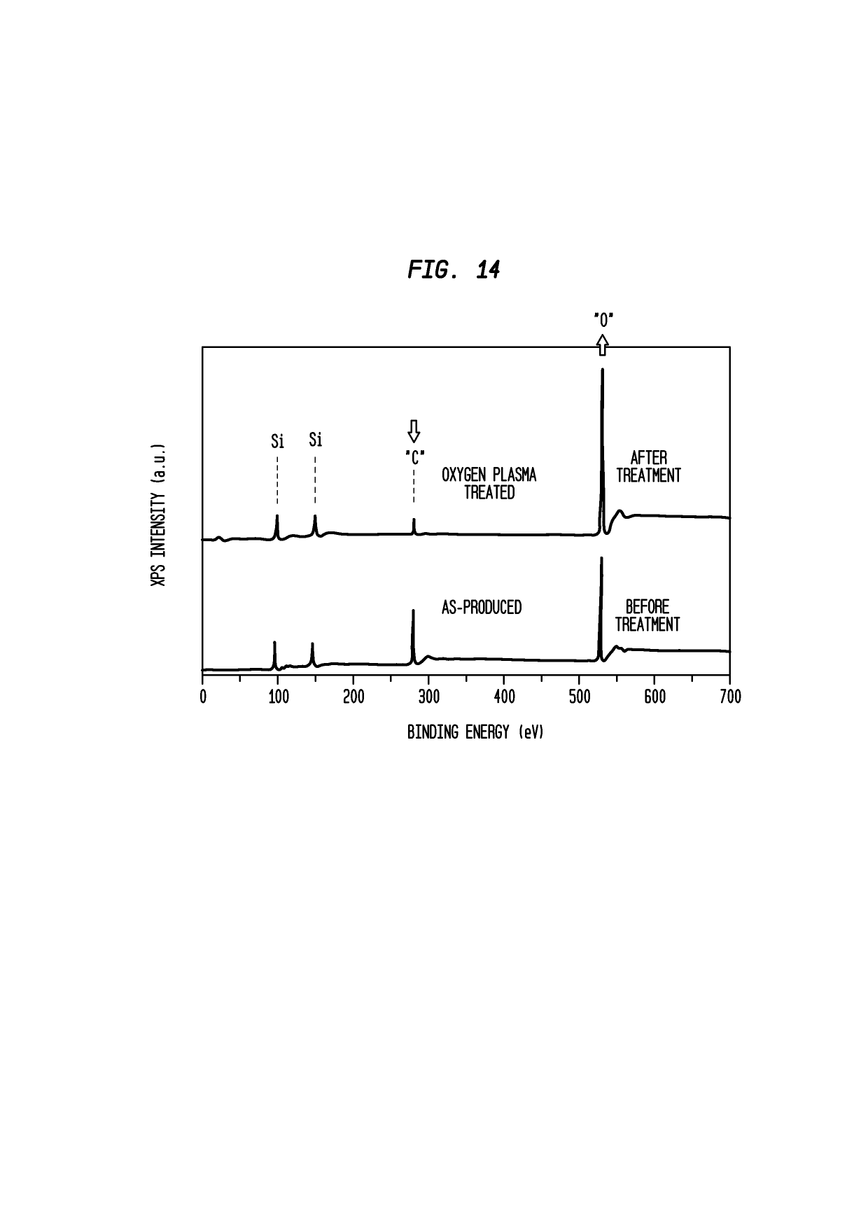

FIGS. 12(a) and 12(b) show one embodiment of treating compound 30 to form the SFCL along and into outer surfaces 34. FIG. 12(a) represents untreated surfaces 34 of compound 30, while FIG. 12(b) represents surface 34 after they have been plasma or otherwise treated to form the SFCL along and into surfaces 34. In the example of FIG. 12(b), the SFCL contains functional OH groups, which experimentation has shown decreases water contact angles therealong from 108 degrees, plus or minus 2 degrees, to 0 degrees, plus or minus 2 degrees. Such OH functional groups therefore increase wettability characteristics and promote the flow of molding compounds thereover, such as molding compound 28. Such functional groups also tend to covalently bond with epoxy and other components in molding compound 28 when placed in close proximity thereto, as shown in FIGS. 13(a) and 13(b), where according to one embodiment epoxy polymer-amine groups (NH₂ or NH) form at the interface between optically reflective compound 30 and molding compound 28. As those skilled in the art will now understand, to functional groups that promote adhesion and increase breakdown voltages between optically reflective compound 30 and molding compound 28 are contemplated other than those disclosed explicitly herein.

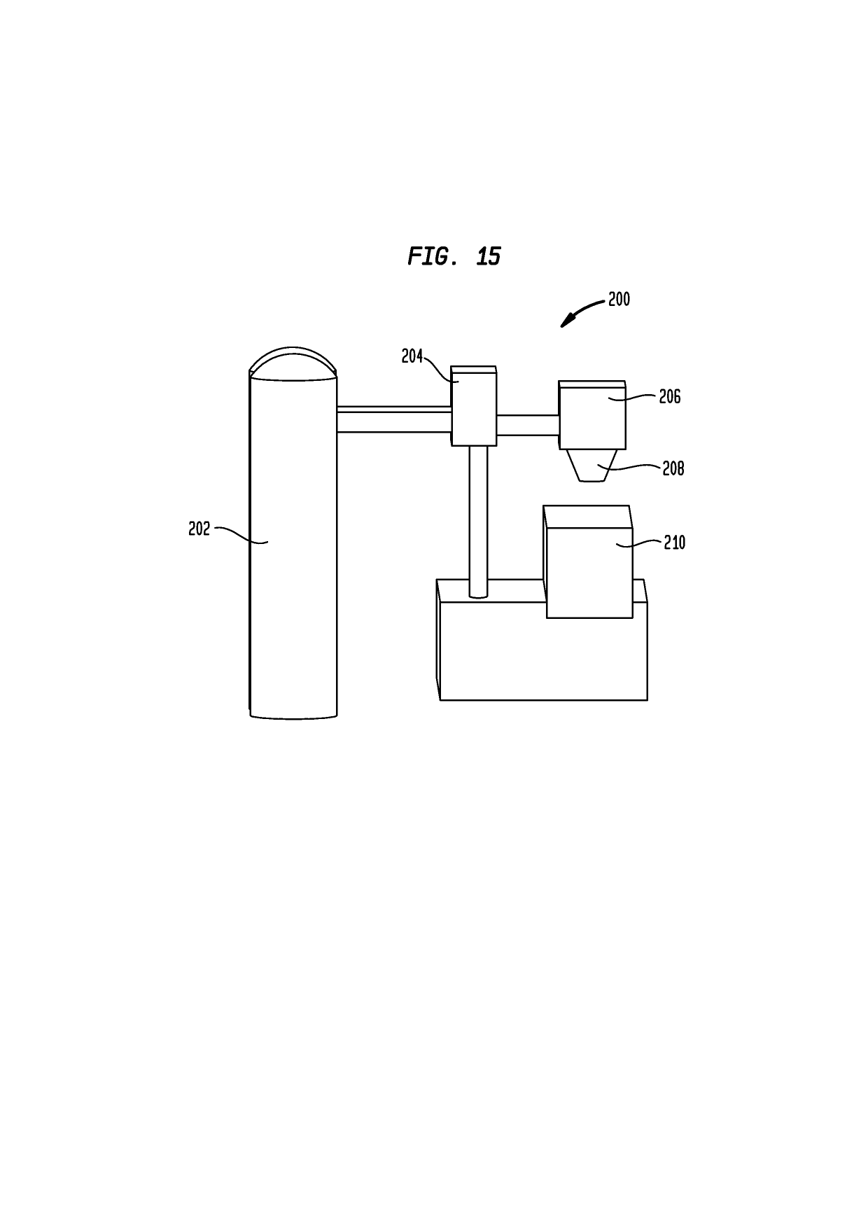

FIG. 14 shows experimental results obtained using one embodiment of optically reflective compound 30 before and after plasma treatment to form the SFCL in outer surfaces 34 thereof. As shown, the treated surfaces exhibit a pronounced increase in the peak at about 525 eV, which corresponds to an increase in wettability characteristics (as described above). Further experimentation and comparison in Ramp to Destruct (RTD) failure modes has shown that the SFCL in compound 30 can increase breakdown voltages from 7.0-9.5 kV (no SFCL in compound 30) to 11.5-12.5 kV (SFCL in compound 30), which further confirms that the SFCL improves adhesion strength between compounds 30 and 28, and increases the reliability of package 10. Fewer gaps have been discovered between inner walls 46 and outer surfaces 34 of packages 10 where outer surfaces 34 have been plasma treated to form SFCLs.

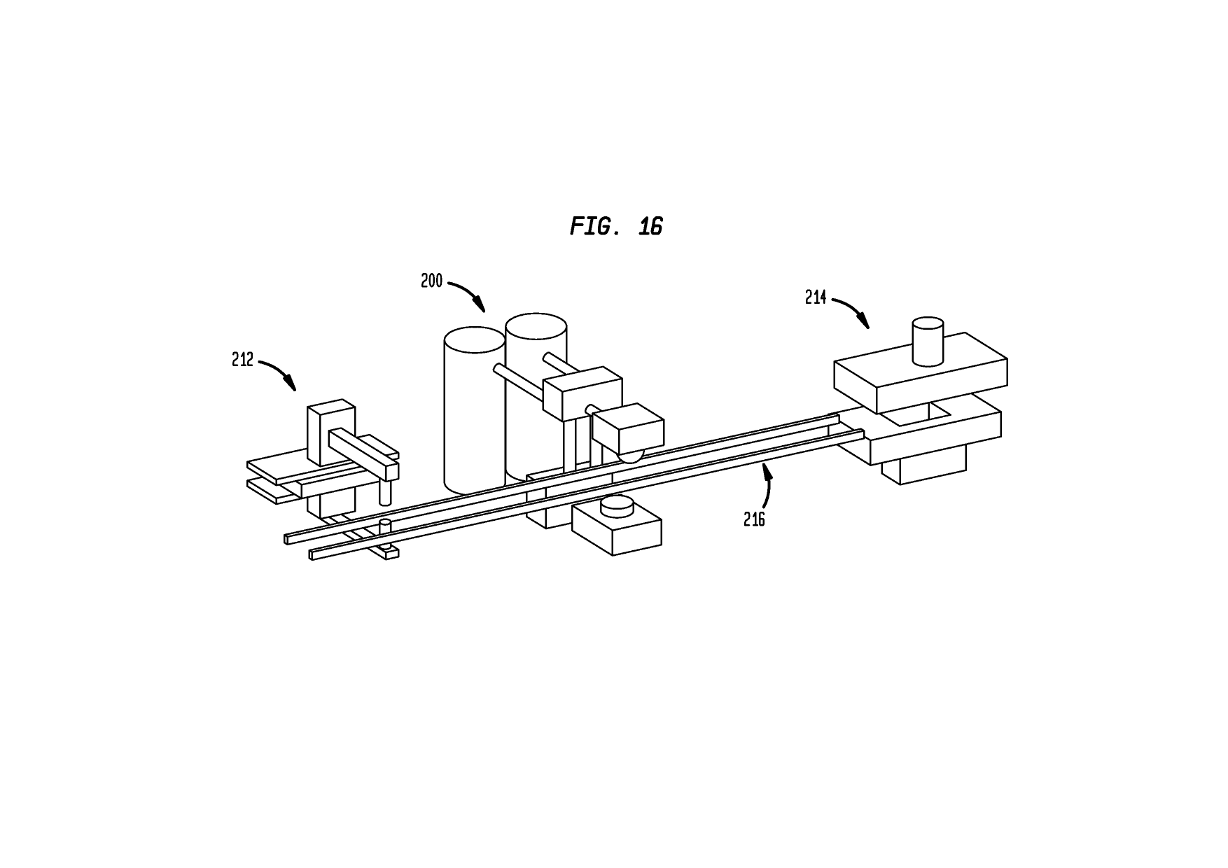

FIGS. 15 and 16 illustrate some embodiments of equipment that can be used to treat optically reflective compound 30 to form the SFCL along and into surfaces 34 thereof. In FIG. 15, gas cylinder 202 provided a suitable inert gas that is mixed with oxygen, for example, in gas mixer 204 for delivery through plasma and anchoring molecule/chemical generator 206 and plasma tip 208 onto surfaces 34 of package 10 presented to tip 208 by XYZ stage 210. Some examples of gases that may be employed to form the SFCLs in outer surfaces 34 include, but are not limited to, mixtures of argon and oxygen (O₂), helium and oxygen (O₂), and nitrogen and oxygen (O₂). FIG. 16 shows an SFCL-forming equipment line that includes SFCL equipment 200, silicone dispensing equipment 212 (for dispensing compound 30), and molding equipment 216 (for forming to enclosure 36 with molding compound 28 over plasma treated compound 30).

The above-described embodiments should be considered as examples of the present invention, rather than as limiting the scope of the invention. In addition to the foregoing embodiments of the invention, review of the detailed description and accompanying drawings will show that there are other embodiments of the present invention. Accordingly, many combinations, permutations, variations and modifications of the foregoing embodiments of the present invention not set forth explicitly herein will nevertheless fall within the scope of the present invention.

We claim:

1. An optocoupler package, comprising:
a light emitting diode (LED);
at least one photodetector;
a first lead frame comprising an LED connection site and a first pin connection portion;
a second lead frame comprising a photodetector connection site and a second pin connection portion;
a molding compound comprising epoxy, and
an optically reflective compound comprising silicone and inner and outer surfaces;
wherein the LED is operably connected to the first lead frame at the LED connection site, the photodetector is operably connected to the second lead frame at the photodetector connection site, the molding compound surrounds and encapsulates portions of the first and second lead frames between the die connection sites and pin connection portions thereof to form an enclosure, the enclosure comprising an interior chamber having inner walls engaging and in contact with at least portions of the outer surfaces of the optically reflective compound, the LED and photodetector are disposed within the chamber and configured with respect to at least portions of the inner surfaces of the optically reflective compound such that at least portions of light emitted by the LED are reflected from the at least portions of such inner surfaces towards the photodetector, and the outer surfaces of the optically reflective compound comprise a surface functional coating layer configured to promote adhesion and increase breakdown voltages between the inner walls of the enclosure and the outer surfaces of the optically reflective compound.

2. The optocoupler package of claim 1, wherein the LED is incorporated into an integrated circuit (IC) die.

3. The optocoupler package of claim 1, wherein the photodetector is incorporated into an integrated circuit (IC) die.

4. The optocoupler package of claim 1, wherein an optically transmissive compound comprising silicone is disposed between the inner surfaces of the optically reflective compound and the LED and the photodetector.

5. The optocoupler package of claim 1, wherein the optically reflective compound comprises white silicone.

6. The optocoupler package of claim 1, wherein the LED is wirebonded to the first lead frame.

7. The optocoupler package of claim 1, wherein the photodetector is wirebonded to the second lead frame.

8. The optocoupler package of claim 1, wherein the outer surface of the optically reflective compound is covalently bonded to at least portions of the inner walls of the interior chamber.

9. The optocoupler package of claim 1, wherein the molding compound is a black epoxy molding compound.

10. The optocoupler package of claim 1, wherein the optically reflective compound comprises a mixture of clear silicone and a white powder.

11. The optocoupler package of claim 1, wherein the package is an 8-pin dual in-line package (DIP).

12. The optocoupler package of claim 1, wherein the package is an opto-isolator.

13. The optocoupler package of claim 1, wherein an interface between the surface functional coating layer and the inner walls is configured to withstand breakdown voltages of at least 10 kV.

14. The optocoupler package of claim 1, wherein an interface between the surface functional coating layer and the inner walls is configured to withstand breakdown voltages of at least 12 kV.

15. The optocoupler package of claim 1, wherein the surface functional coating layer comprises hydroxyl functional groups.

16. The optocoupler of claim 1, wherein the photodetector is one of a photo diode, a bipolar detector transistor, and a Darlington detector transistor.

17. The optocoupler of claim 1, wherein the LED is one of an AlGaAs LED, an ACE AlGaAs LED, a DPUP AlGaAs LED, and a GaAsP LED.

18. A method of making an optocoupler package comprising a light emitting diode (LED), at least one photodetector, a first lead frame comprising an LED connection site and a first pin connection portion, a second lead frame comprising a photodetector connection site and a second pin connection portion, a molding compound comprising epoxy, and an optically reflective compound comprising silicone inner and outer surfaces, the method comprising:
attaching the LED to the LED connection site on the first lead frame and then wirebonding same to the first lead frame to form a first wirebond;
attaching the photodetector to the photodetector connection site on the second lead frame and then wirebonding same to the second lead frame to form a second wire bond;
encapsulating the LED, the photodetector, and portions of the first and second lead frames disposed near the LED and the photodetector with an optically transmissive compound comprising silicone;
encapsulating the optically transmissive compound and portions of the first and second lead frames with an optically reflective compound comprising silicone, the optically reflective compound comprising inner surfaces that engage the optically transmissive compound and outer surfaces;
treating at least portions of the outer surfaces of the optically reflective compound to form a surface functional coating layer thereon, and
overmolding the outer surfaces of the optically reflective compound and portions of the first and second lead frames with a molding compound comprising epoxy to form an enclosure having inner walls;
wherein the surface functional coating layer is configured to promote adhesion and increase breakdown voltages between the inner walls of the enclosure and at least portions of the outer surfaces of the optically reflective compound.

19. The method of claim 18, wherein treating further comprises plasma treating the at least portions of the outer surfaces.

20. The method of claim 19, wherein plasma treating further comprises employing a carrier gas selected from the group consisting of argon, helium and nitrogen.

21. The method of claim 20, wherein plasma treating further comprises providing employing the carrier gas at a rate ranging between about 1.0 liters per minute and about 10 liters per minute.

22. The method of claim 18, wherein plasma treating further comprises employing a reaction gas comprising oxygen.

23. The method of claim 19, wherein plasma treating further comprises providing employing the reaction gas at a rate ranging between about 10 standard cubic centimeters per minute (sccm) and about 50 sccm.

24. The method of claim 19, wherein plasma treating occurs at approximately atmospheric pressure.

25. The method of claim 19, wherein plasma treating further comprises employing radio frequency (RF) power ranging between about 50 watts and about 200 watts.

26. The method of claim 18, further comprising configuring the LED and photodetector with respect to at least portions of the inner surfaces of the optically reflective compound such that at least portions of light emitted by the LED are reflected from the at least portions of such inner surfaces towards the photodetector.
